(19) United States
(12) Patent Application Publication
(10) Pub. No.: US 2017/0098724 A1
(43) Pub. Date: Apr. 6, 2017

(54) CUTTABLE SOLAR WRAP

(71) Applicant: Toyota Motor Engineering & Manufacturing North America, Inc., Erlanger, KY (US)

(72) Inventor: Geoffrey D. Gaither, Torrance, CA (US)

(21) Appl. No.: 14/873,543

(22) Filed: Oct. 2, 2015

(51) Int. Cl. H01L 31/0465

(52) U.S. Cl. CPC H01L 31/0465

(57) ABSTRACT

A cuttable solar wrap includes a flexible, sheet-like substrate. A photovoltaic grid, having photovoltaic cells or submodules connected in parallel by internal conductors is incorporated into the substrate. The cuttable solar wrap further includes a plurality of spaced-apart power transfer wires protruding from the substrate, each power transfer wire independently configured to incorporate the solar grid into a circuit. This arrangement enables the solar wrap to be cut at any location, producing pieces, such that each piece retains full photovoltaic function and is independently and effectively able to be incorporated into a circuit without further modification.

### TECHNICAL FIELD

The present disclosure generally relates to photovoltaic devices, and more particularly, to a cuttable, flexible photovoltaic wrap.

### BACKGROUND

The background description provided herein is for the purpose of generally presenting the context of the disclosure. Work of the presently named inventors, to the extent it may be described in this background section, as well as aspects of the description that may not otherwise qualify as prior art at the time of filing, are neither expressly nor impliedly admitted as prior art against the present technology.

Design and implementation of a solar array for a specific site can be an expensive and time consuming task. In particular, solar array deployments on curved surfaces, in small spaces, in conditions of use involving high winds or other environmental stressors, or with size and shape requirements can be very specific and not amenable to cross-platform utilization.

Accordingly, it would be desirable to provide a device for solar harvesting that can be easily retro-fitted to a wide variety of surfaces and environments.

### SUMMARY

This section provides a general summary of the disclosure, and is not a comprehensive disclosure of its full scope or all of its features.

In various aspects, the present teachings provide a cuttable solar wrap. The cuttable solar wrap includes a flexible, substantially two-dimensional substrate and a plurality of power transfer lines protruding from the substrate at intervals. Each power transfer line is configured to independently incorporate the wrap into an electric circuit. The wrap further includes a photovoltaic grid integrated into and substantially coplanar and coextensive with the substrate. The grid includes a plurality of photovoltaic nodes periodically arrayed in two directions, and a plurality of flexible internal conductors connecting the plurality of photovoltaic nodes in electric parallel with one another.

In other aspects, the present teachings provide a cuttable solar wrap as above in which the photovoltaic grid includes a two-dimensional array of repeating unit cells. Each unit cell includes at least three photovoltaic nodes and at least three flexible internal conductors. Each flexible conductor connect two photovoltaic nodes in electric parallel.

In still other aspects, the present teachings provide a method for producing photovoltaic function at a surface. The method includes a step of cutting a solar wrap of the type referenced above. The method further includes a step of applying the cut solar wrap to the surface. The method further includes a step of incorporating the cut solar wrap into an electrical circuit using at least one power transfer line.

Further areas of applicability and various methods of enhancing the above coupling technology will become apparent from the description provided herein. The description and specific examples in this summary are intended for purposes of illustration only and are not intended to limit the scope of the present disclosure.

### BRIEF DESCRIPTION OF THE DRAWINGS

The present teachings will become more fully understood from the detailed description and the accompanying drawings, wherein:

FIG. 1 is a perspective view of a cuttable solar wrap of the present disclosure;

FIG. 2 is a top view of a cuttable solar wrap with a photovoltaic grid shown;

FIG. 3 is a side cross-sectional view of the flexible solar wrapanel of FIG. 2;

FIG. 4A is a schematic side view of two photovoltaic nodes in a variation wherein each photovoltaic node is a photovoltaic cell;

FIG. 4B is a schematic side view of a photovoltaic node in a variation in which each photovoltaic node is a photovoltaic submodule;

FIG. 5A is a top view of a cuttable solar wrap in which the photovoltaic grid includes a plurality of hexagonal unit cells;

FIG. 5B is a top view of a cuttable solar wrap in which the photovoltaic grid includes a plurality of trigonal unit cells; and

FIG. 6 is a schematic side view of an automobile having a cut solar wrap affixed to hood, roof, and trunk surfaces.

It should be noted that the figures set forth herein are intended to exemplify the general characteristics of the methods, algorithms, and devices among those of the present technology, for the purpose of the description of certain aspects. These figures may not precisely reflect the characteristics of any given aspect, and are not necessarily intended to define or limit specific embodiments within the scope of this technology. Further, certain aspects may incorporate features from a combination of figures.

### DETAILED DESCRIPTION

The present disclosure describes a cuttable photovoltaic wrap configured to retain solar harvesting and power transmitting functions even when cut into two or more pieces, regardless of the shape or location of a cut. The ability to be cut to any shape without loss of function can make the wrap a cost-effective means for incorporating solar harvesting and power transmission function to a wide variety of surfaces or objects. Thus the disclosed solar wrap can be prefabricated in a generic shape, and subsequently cut into pieces for application to any surface, all cut pieces being useable for photovoltaic power generation. In one example, the wrap can be useful for incorporating photovoltaic generation capability to automobile surfaces, such as hood, roof, or trunk.

The cuttable photovoltaic wrap includes a flexible substrate incorporated with a network of photovoltaic (solar) cells. The photovoltaic cells are arranged in a two-dimensional, grid-like pattern, interconnected by a plurality of internal conductors. External conductors protrude from the wrap intermittently, such that any external conductor can provide electric leads sufficient to connect the wrap to a load or otherwise integrate the wrap to an electric circuit.

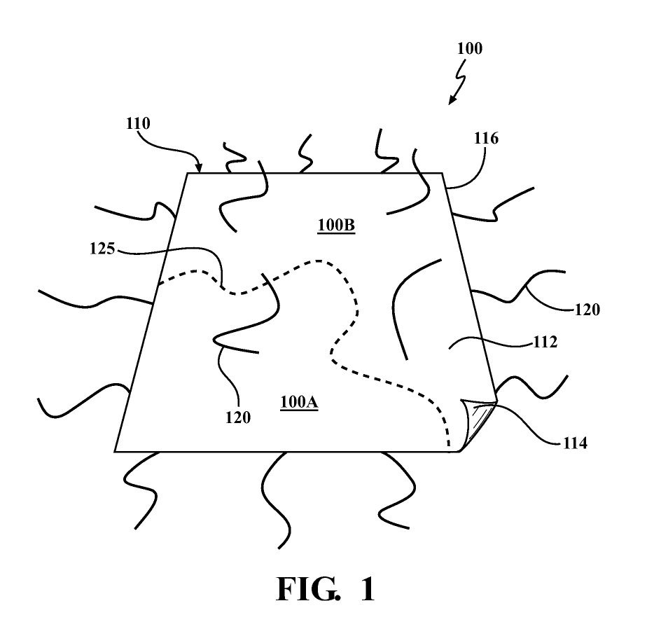

Accordingly, and with reference to FIG. 1, a cuttable photovoltaic, or solar, wrap 100 is disclosed. The solar wrap 100 includes a flexible substrate 110. The flexible substrate 110 can be composed at least in part of an elastomeric, viscoelastic, or other plastic polymeric material. The flexible substrate 110 can optionally include one or more plasticizers to increase flexibility. Non-limiting examples of suitable polymeric materials for incorporation in the flexible substrate 110 include a vinyl polymer or copolymer such as polyvinylchloride or polyethylene terephthalate, a polyorganosilane (silicone), and a nylon.

Typically, the flexible substrate 110 possesses a substantially two-dimensional shape, such as a sheet as in FIG. 1, a web, grid, perforated sheet, or other shape suitable to support other components of the wrap 100. As shown in FIG. 1, the flexible substrate 110 can be characterized as having a first surface 112, a second surface 114 that is opposite the first surface 112, and a perimeter 116.

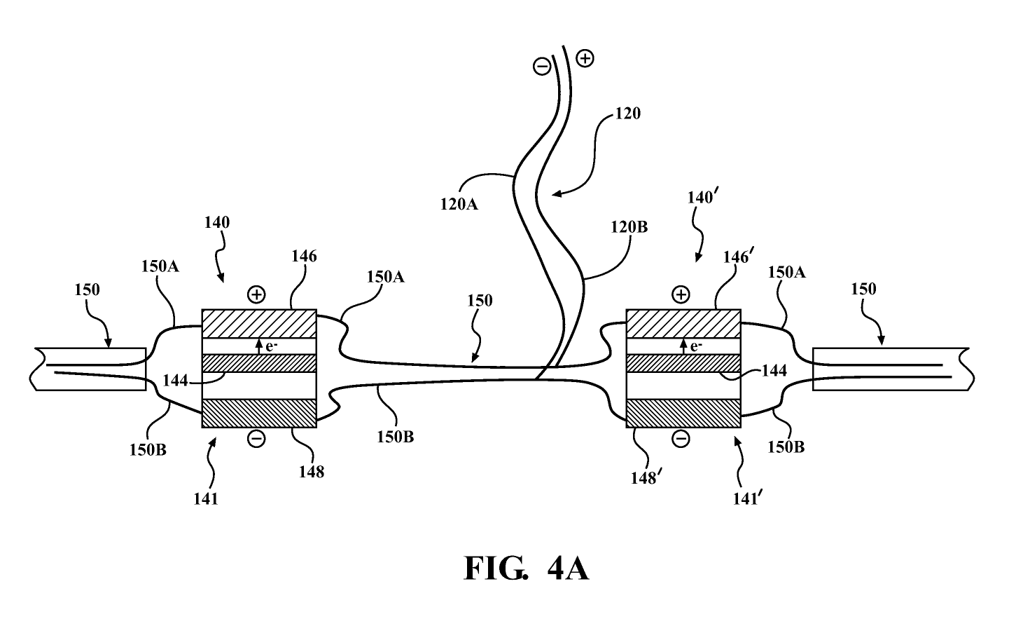

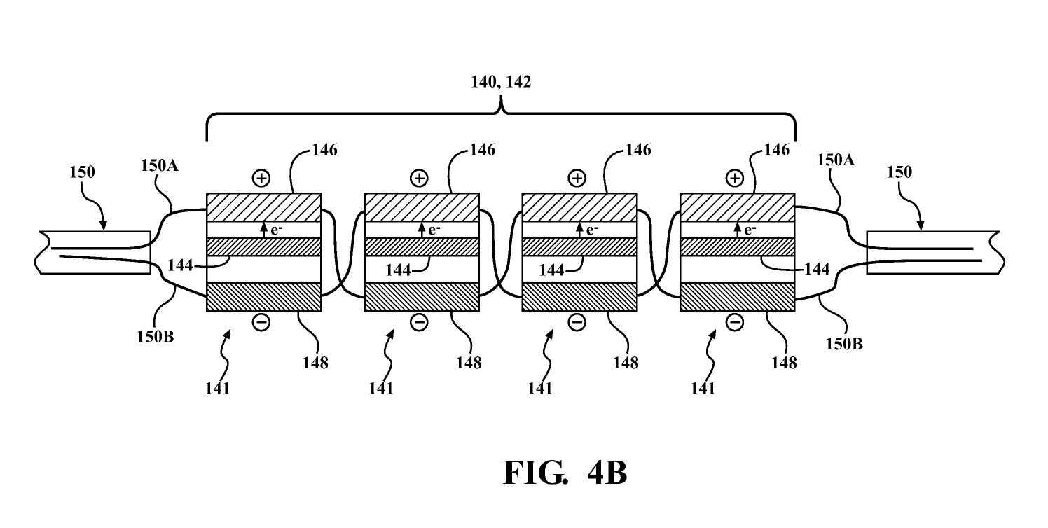

The wrap 100 can include a plurality of power transfer lines 120, each power transfer line 120 independently configured to incorporate the wrap 100 into an electric circuit with a load. In some implementations, a power transfer line 120 can include two insulated conductors 120A and 120B having opposite polarity relative to one another (see FIG. 4A). An individual power transfer line 120 can protrude from any of the first surface 112, the second surface 114, and the perimeter 116. Referring to the specific example of FIG. 1, the wrap 100 is configured so that it can be cut into pieces along any cut line, such as the cut line 125, producing wrap 100 pieces 100A and 100B. Any power transfer line 120 located on wrap piece 100A can be employed to incorporate wrap piece 100A into a circuit. Similarly, any power transfer line 120 located on wrap piece 100B can be employed to incorporate wrap piece 100B into a circuit.

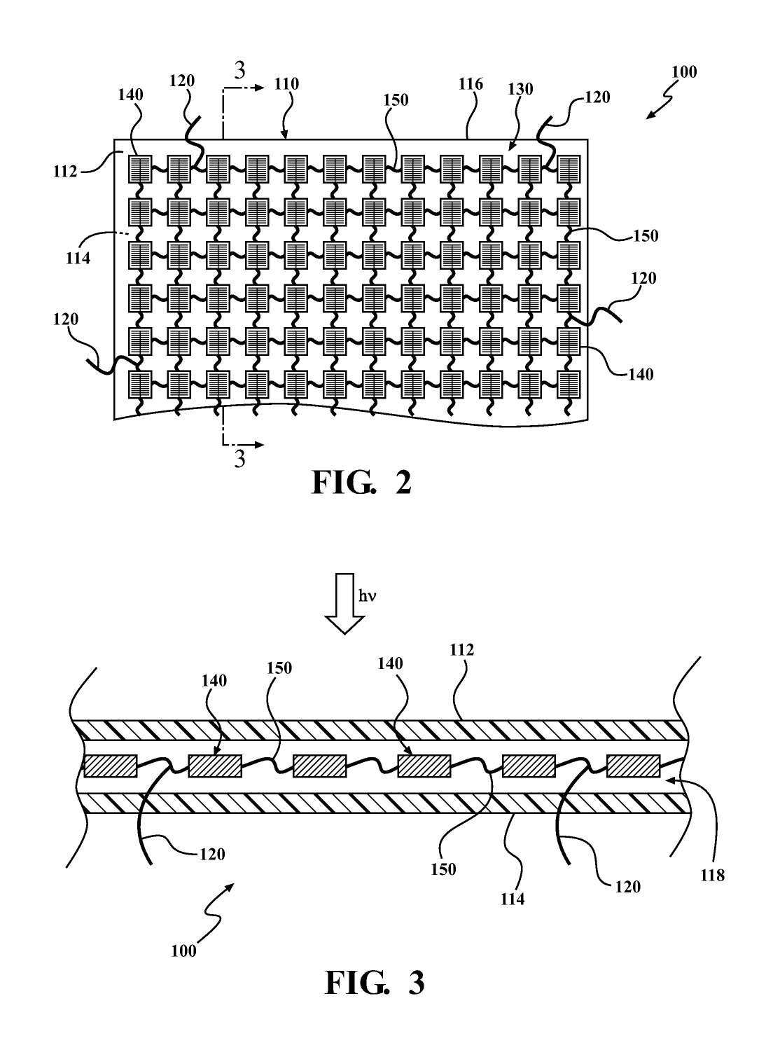

Referring now to FIGS. 2 and 3, the solar wrap 100 further includes a photovoltaic grid 130 supported by the flexible substrate 110. The photovoltaic grid 130 includes a plurality of photovoltaic nodes 140 periodically arrayed in two dimensions across the flexible substrate 110. In some implementations, and with reference to FIG. 4A, an individual photovoltaic node 140 of the photovoltaic grid can be an individual photovoltaic cell 141. In some implementations, and with reference to FIG. 4B, an individual photovoltaic node 140 can be a photovoltaic submodule 142 formed from a plurality of interconnected photovoltaic cells 141.

The photovoltaic grid 130 can further include a plurality of internal conductors 150 configured to place the photovoltaic nodes 140 in electrical communication with one another. Each internal conductor 150 of the plurality can be formed as a wire, filament, or strip of an electrically conductive material. The electrically conductive material can be a metal, such as copper; an inorganic oxide, such as tin oxide; a conductive organic polymer, such as polyacetylene; or any other material able to conduct electric current with relatively low thermal conversion.

Each internal conductor 150 of the plurality can place an individual photovoltaic node 140 of the plurality in electrical communication with another photovoltaic node 140 of the plurality. In some implementations, the plurality of internal conductors 150 and the plurality of photovoltaic nodes 140 will be arranged such that each photovoltaic node 140 of the plurality is in electrical communication with at least three adjacent photovoltaic nodes 140 of the plurality. In some implementations, the plurality of internal conductors 150 and the plurality of photovoltaic nodes 140 can be arranged so individual photovoltaic nodes of the plurality are in electric parallel with one another. It will be appreciated that a two-dimensional array of photovoltaic nodes in electric parallel with one another can create electric circuit pathway redundancies that can facilitate retention of function when the wrap 100 is cut. In some implementations, each internal conductor 150 can be equipped with “slack”, i.e. possessing a greater maximum length than the distance between the photovoltaic nodes 140 that it connects. Slack in the internal conductors 150 can also be described as internal conductors 150 being not taut. Such slack can be useful in improving flexibility of the wrap 100.

As shown in FIG. 3, a side cross-sectional view of the solar wrap 100 taken along the line 3-3 of FIG. 2, the flexible substrate 110 can optionally be formed of two or more laminate layers. In the particular example of FIG. 3, the flexible substrate 110 is composed of a first laminate 160 and a second laminate 170 with an internal region 118 located between them. In this instance, the photovoltaic grid 130 is positioned in the internal region 118 between the first and second laminates 160, 170. As shown by the arrow representing incident light, the first laminate 160 in the example of FIG. 4 can be regarded as an outer layer, a layer through which incident light must pass in order to reach the photovoltaic grid, and the second laminate 170 can be regarded as an inner layer, a layer through which light need not necessarily pass and which can be contacted with a surface such as a car roof during deployment. While the schematic illustration of FIG. 4 suggests a significant separation distance between the first and second laminates 160, 170 this need not necessarily be so, and instead the first and second laminates 160, 170 can be substantially in contact with one another.

In instances where the photovoltaic grid is positioned between first and second laminates 160, 170, it will generally be preferable for at least one of the laminates to be transparent to a wavelength of light to which the photovoltaic nodes are reactive. The other laminate can, in different configurations, variously be transparent, opaque, or reflective. While the example of FIG. 3 shows the photovoltaic grid positioned in the internal region 118 between two laminate layers, it will be appreciated that the flexible substrate 110 can be composed of a single layer or of more than two laminate layers. It will further be appreciated that the photovoltaic grid can be positioned in an internal region 118 as shown, or at either of the first and second surfaces 112, 114.

FIG. 4A shows two photovoltaic nodes 140 of the solar wrap 100 of FIG. 1, where each photovoltaic node 140, 140′ is a photovoltaic cell 141, 141′. The photovoltaic cell 141 can be any type of photovoltaic cell, including without limitation a crystalline or amorphous silicon solar cell, a dye-sensitized solar cell, and an organic solar cell. In some implementations, a photovoltaic cell 141 can be a thin film photovoltaic cell, including without limitation any of a copper indium gallium selenide solar cell, a cadmium telluride solar cell, and an amorphous silicon solar cell.

In general, the photovoltaic cell 141 has a photovoltaic electron donor 144 in electrical communication with a current collector of a first polarity 146. Electrical polarity (i.e. the first polarity) of the current collector of a first polarity 146 is generally represented in the drawings with a “positive” symbol, and the current collector of a first polarity 146 will alternatively be referred to herein as a cathode. The photovoltaic cell 141 further includes a current collector of a second polarity 148. Electrical polarity (i.e. the second polarity) of the current collector of a second polarity 148 is generally represented in the drawings with a “negative” symbol, and the current collector of a second polarity 146 will alternatively be referred to herein as an anode.

As shown in the configuration of FIG. 4A, photovoltaic nodes 140 can be connected to one another in electric parallel (cathode-to-cathode and anode-to-anode) by internal conductors 150. In the specific example of FIG. 4A, internal conductor 150 includes two separate conductors: (i) a cathodic conductor 150A that is configured to electrically connect a cathode 146 of a first photovoltaic node 140 with a cathode 146′ of an adjacent photovoltaic node 140′, and (ii) an anodic conductor 150B that is configured to electrically connect an anode 148 of the first photovoltaic node 140 with an anode 148′ of the adjacent photovoltaic node 140′. Thus when the wrap 100 is incorporated into a circuit and exposed to light, the anode 146 is effective to receive electron flow from the electron donor 144 and transmit the electron flow to cathodic conductor 150A. Similarly, anodic conductor 150B is configured to return electron flow to anode 148, where it will ultimately be returned to electron donor 144.

With continuing reference to FIG. 4A, in some implementations in which internal conductors 150 include two separate power transfer conductors 150A, 150B of opposite polarity, individual power transfer lines 120 can include two power transfer conductors 120A and 120B of opposite polarity. As shown in FIG. 4A, the power transfer conductor of a first polarity 150A is connected to the cathodic conductor 150A and the power transfer conductor of a second polarity 150B is connected to the anodic conductor 150B. In such a configuration, individual power transfer lines 120 form two-way wires, facilitating incorporation into a circuit, for example by enabling connection of the power transfer conductor of a first polarity 150A and the power transfer conductor of a second polarity 150B to opposite termini of a battery or other device.

As noted above, and with reference to FIG. 4B, in some implementations a photovoltaic node 140 can be a photovoltaic submodule 142. In many implementations, a photovoltaic submodule 142 can include a plurality of photovoltaic cells 141 connected in series (anode-to-cathode and cathode-to-anode). FIG. 4B schematically illustrates a photovoltaic node 140 including a photovoltaic submodule 142 made of four photovoltaic cells 141 connected in series. Internal conductors 150 are connected to the first and last photovoltaic cells 141 in the series in the same manner as described in conjunction with FIG. 4A, and connect the photovoltaic submodule 142 in parallel with at least three adjacent photovoltaic submodules. It will be appreciated that the schematic example of serial connectivity between photovoltaic cells 141 within a photovoltaic submodule 142 for use as a photovoltaic node 140 may be of particular use when the electric potential difference, ΔV, provided by a single photovoltaic cell 141 is insufficient for a given application.

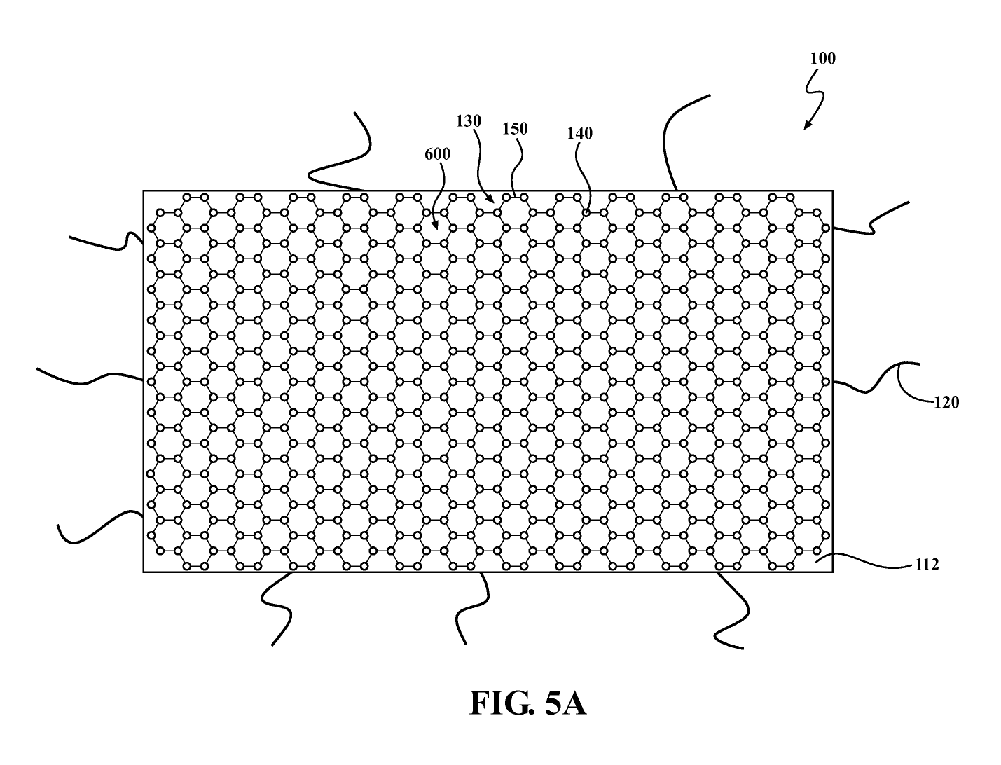

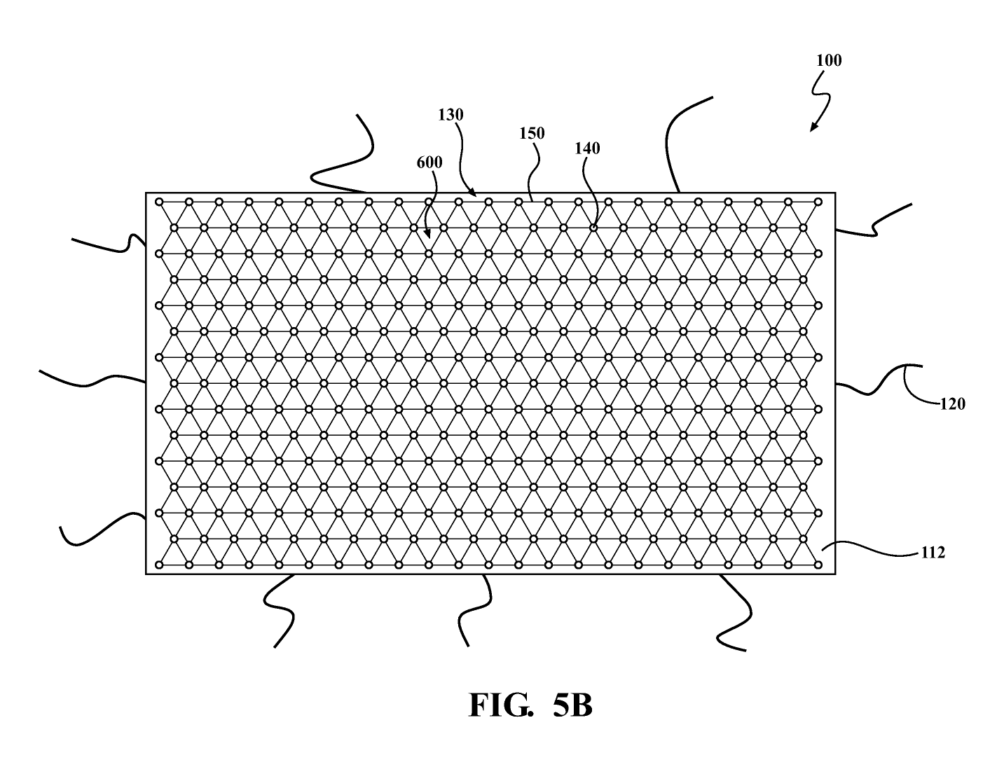

With reference to FIGS. 5A and 5B, in some implementations, the photovoltaic grid 130 can include a plurality of periodic unit cells 600. Each unit cell 600 of the plurality can have a polygonal shape, such as the trigonal unit cell of FIG. 5B, the hexagonal unit cell of FIG. 5A, or the tetragonal unit cell of FIG. 2. Each unit cell 600 can be equilateral as shown. In general, each unit cell will include at least three internal conductors 150 and at least three photovoltaic nodes 140, with each internal conductor placing two adjacent photovoltaic nodes in electrical communication with each other. It will further be appreciated that the solar wrap 100 of FIG. 5A, having hexagonal unit cells 600, is an example in which each photovoltaic node 140 is directly connected to exactly three adjacent photovoltaic nodes 140. Similarly, the solar wrap 100 of FIG. 5B, having trigonal unit cells 600, is an example in which each photovoltaic node 140 is directly connected to six adjacent photovoltaic nodes 140. Similarly, the solar wrap 100 of FIG. 2, having tetragonal unit cells, is an example in which each photovoltaic node 140 is directly connected to four adjacent photovoltaic nodes 140.

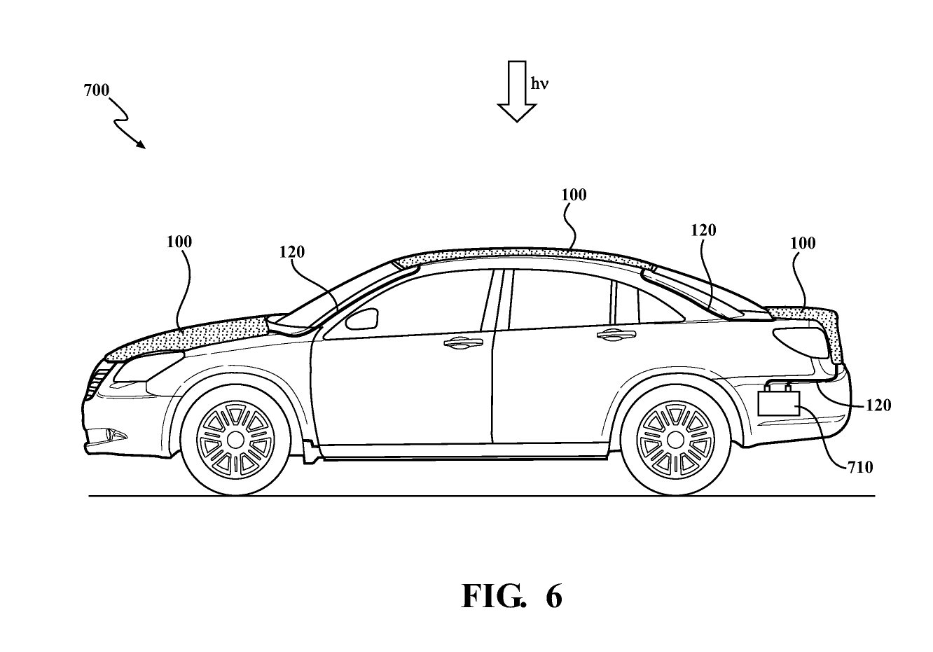

As shown in FIG. 6, a solar wrap 100 can be applied to any surface to provide a solar harvesting function at that surface. In the specific example of FIG. 6, the solar wrap 100 is applied to an exterior of hood, roof, and trunk surfaces of an automobile 700 and placed in electrical communication with a vehicle battery 710 to perform battery charging when the automobile 700 is exposed to light. Because the solar wrap 100 can be cut to shape while retaining functionality as described above, a solar wrap 100 of generic shape can be retrofitted and applied to the vehicle 700, or any other surface, post-production. Thus, a disclosed method for producing photovoltaic function at a surface includes a step of cutting a photovoltaic wrap 100, the photovoltaic wrap 100 being as described above. Typically, the cutting step will involve cutting the solar wrap to a specific shape that covers or otherwise accommodates the surface. The method additionally includes a step of applying the cut solar wrap 100 to the surface. The applying step can be performed by resting the cut solar wrap 100 on the surface or by affixing the cut solar 100 wrap to the surface, such as with an adhesive. The method can additionally include a step of incorporating the cut solar wrap 100 into an electrical circuit, using at least one power transfer line 120. An example of such an electrical circuit is shown in FIG. 6, where a cut solar wrap 100 is connected to the battery 710 via a power transfer line 120.

The foregoing description of the embodiments has been provided for purposes of illustration and description. It is not intended to be exhaustive or to limit the disclosure. Individual elements or features of a particular embodiment are generally not limited to that particular embodiment, but, where applicable, are interchangeable and can be used in a selected embodiment, even if not specifically shown or described. The same may also be varied in many ways. Such variations should not be regarded as a departure from the disclosure, and all such modifications are intended to be included within the scope of the disclosure.

What is claimed is:

1. A cuttable solar wrap, comprising:
a substrate;
a plurality of power transfer lines protruding from the substrate, with individual power transfer lines configured to independently incorporate the wrap into an electric circuit; and
a photovoltaic grid comprising:
a plurality of photovoltaic nodes periodically arrayed in two directions; and
a plurality of flexible internal conductors connecting the plurality of photovoltaic nodes in electric parallel with one another.

2. The cuttable solar wrap as recited in claim 1, wherein each photovoltaic node of the plurality is a photovoltaic cell.

3. The cuttable solar wrap as recited in claim 1, wherein each photovoltaic node of the plurality comprises a photovoltaic submodule, the photovoltaic submodule comprising a plurality of photovoltaic cells.

4. The cuttable solar wrap as recited in claim 3, wherein the plurality of photovoltaic cells are connected in electric series with one another.

5. The cuttable solar wrap as recited in claim 1, wherein each of the substrate and the photovoltaic grid is flexible.

6. The cuttable solar wrap as recited in claim 1, wherein the substrate is substantially two-dimensional, having a first surface, a second surface opposite the first surface, and a perimeter.

7. The cuttable solar wrap as recited in claim 6, wherein the photovoltaic grid is substantially coplanar and coextensive with the substrate.

8. The cuttable solar wrap as recited in claim 6, wherein power transfer lines of the plurality of power transfer lines protrude from any of the first surface, the second surface, and the perimeter at intervals.

9. The cuttable solar wrap as recited in claim 6, wherein the substrate comprises a first laminate, a second laminate substantially coplanar with the first laminate, and an interior region located between the first and second laminates.

10. The cuttable solar wrap as recited in claim 9, wherein the photovoltaic grid is located in the interior region.

11. The cuttable solar wrap as recited in claim 9, wherein he first laminate is substantially transparent to incident light.

12. The cuttable solar wrap as recited in claim 11, wherein the second laminate is substantially reflective of incident light.

13. A cuttable solar wrap, comprising:
a flexible, substantially two-dimensional substrate; and
a photovoltaic grid, integrated into and substantially coplanar and coextensive with the substrate, the grid comprising a two-dimensional array of repeating unit cells, each unit cell comprising:
at least three photovoltaic nodes; and
at least three flexible conductors, each flexible conductor connecting two photovoltaic nodes in electric parallel with one another.

14. The cuttable solar wrap as recited in claim 13, wherein individual unit cells of the two-dimensional array of repeating unit cells define an equilateral polygon.

15. The cuttable solar wrap as recited in claim 13, wherein each photovoltaic node of the plurality is a photovoltaic cell.

16. The cuttable solar wrap as recited in claim 13, wherein each photovoltaic node of the plurality comprises a photovoltaic submodule, the photovoltaic submodule comprising a plurality of photovoltaic cells.

17. The cuttable solar wrap as recited in claim 16, wherein the plurality of photovoltaic cells are connected in electric series with one another.

18. A method for incorporating photovoltaic function to a surface of an object, the method comprising:
cutting a solar wrap to a specified shape to accommodate the surface, the solar wrap comprising:
a substrate;
a plurality of power transfer lines protruding from the substrate, with individual power transfer lines of the plurality of power transfer lines configured to independently incorporate the wrap into an electric circuit; and
a photovoltaic grid integrated into the substrate;
applying the cut solar wrap to the surface; and
incorporating the cut solar wrap into an electrical circuit using at least one power transfer line of the plurality of power transfer lines.

19. The method as recited in claim 18, wherein applying the cut solar wrap comprises applying the cut solar wrap to a surface of a vehicle.

20. The method as recited in claim 18, incorporating the cut solar wrap into an electric circuit comprises coupling the power transfer line to a vehicle battery.
